(19) United States
(12) Patent Application Publication
(10) Pub. No.: US 2021/0320008 A1
(43) Pub. Date: Oct. 14, 2021

(54) METHOD FOR FABRICATING SEMICONDUCTOR DEVICE

(71) Applicant: SK hynix Inc., Gyeonggi-do (KR)

(72) Inventor: Jin Woong KIM, Gyeonggi-do (KR)

(21) Appl. No.: 16/938,646

(22) Filed: Jul. 24, 2020

(30) Foreign Application Priority Data
Apr. 10, 2020 (KR) 10-2020-0043724

(51) Int. Cl. H01L 21/28; H01L 29/423

(52) U.S. Cl. CPC H01L 21/28026; H01L 21/28194; H01L 29/4236

(57) ABSTRACT

A method for fabricating a semiconductor device includes: forming a hard mask layer over a semiconductor substrate; forming a trench by etching the semiconductor substrate with the hard mask layer being used; forming a gate dielectric layer on a surface of the trench while hardening the hard mask layer; and forming a gate electrode partially filling the trench over the gate dielectric layer.

### CROSS-REFERENCE TO RELATED APPLICATIONS

The present application claims priority to Korean Patent Application No. 10-2020-0043724, filed on Apr. 10, 2020, which is incorporated herein by reference in its entirety.

### BACKGROUND

### 1. Field

Various embodiments of the present invention relate generally to a method for fabricating a semiconductor device and, more particularly, to a method for fabricating a semiconductor device including a gate dielectric layer.

### 2. Description of the Related Art

Semiconductor devices including integrated circuits may be applied to diverse electronic devices. A semiconductor device may include a plurality of transistors.

A method for forming a transistor may typically include a trench forming process for forming a trench in a substrate by using a hard mask layer. However, because the hard mask layer may be damaged during the recessing process for forming the transistor, an active region below the hard mask layer may also be damaged.

Also, typically, the gate dielectric layer of a transistor may be formed of an oxide layer that is formed by thermally oxidizing the active region. During the thermal oxidation of the active region, silicon loss may occur. Due to silicon loss, the critical dimension of the active region may be reduced and bending may occur.

As a result, the performance of the transistor may be deteriorated.

### SUMMARY

Various embodiments of the present invention are directed to an improved method for fabricating a semiconductor device that is capable, among other things, of protecting a hard mask layer employed in the recessing process of a trench from being damaged. The method may also reduce or prevent damage to the active region.

Various embodiments of the present invention are directed to a method for fabricating a semiconductor device capable of preventing deterioration of the critical dimension of an active region and bending.

In accordance with an embodiment of the present invention, a method for fabricating a semiconductor device includes: forming a hard mask layer over a semiconductor substrate; forming a trench by etching the semiconductor substrate with the hard mask layer being used; forming a gate dielectric layer on a surface of the trench while hardening the hard mask layer; and forming a gate electrode partially filling the trench over the gate dielectric layer.

In accordance with another embodiment of the present invention, a method for fabricating a semiconductor device includes: forming a hard mask layer in a semiconductor substrate; forming a trench by etching the semiconductor substrate with the hard mask layer; forming a gate dielectric layer having a wet etch rate that is different from a wet etch rate of the hard mask layer on a surface of the trench; forming a buried gate structure filling the trench over the gate dielectric layer; forming a first source/drain region and a second source/drain region in the semiconductor substrate on both sides of the buried gate structure; forming a bit line structure contacting the first source/drain region; and forming a storage node contact plug contacting the second source/drain region.

In accordance with another embodiment of the present invention, a method for fabricating a semiconductor device includes: forming a hard mask layer over a semiconductor substrate; forming a trench in the semiconductor substrate using the hard mask layer; forming a gate dielectric layer on a surface of the trench; hardening the hard mask layer; and forming a gate electrode in the trench over the gate dielectric layer.

Wherein the hardening of the hard mask layer is performed simultaneously with the formation of gate dielectric layer.

Wherein the hardening of the hard mask layer is formed by oxidation performed after the formation of the gate dielectric layer.

These and other features and advantages of the present invention may be better understood from the following description of detailed embodiments in reference with the accompanying drawings.

### BRIEF DESCRIPTION OF THE DRAWINGS

FIG. 1 is a plan view illustrating a semiconductor device in accordance with an embodiment of the present invention.

FIG. 2A is a cross-sectional view taken along a line A-A′ shown in FIG. 1.

FIG. 2B is a cross-sectional view taken along a line B-B′ shown in FIG. 1.

FIGS. 3A to 3H are cross-sectional views illustrating a method for fabricating a semiconductor device in accordance with a first embodiment of the present invention.

FIGS. 4A to 4F are cross-sectional views illustrating a method for fabricating a semiconductor device in accordance with a second embodiment of the present invention.

FIGS. 5A to 5K are cross-sectional views illustrating a method for fabricating a memory cell in accordance with various embodiments of the present invention.

FIGS. 6A to 6G are cross-sectional views illustrating semiconductor devices in accordance with various embodiments of the present invention.

### DETAILED DESCRIPTION

Various embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

It will be further understood that when an element is referred to as being “connected to”, or “coupled to” another element, it may be directly on, connected to, or coupled to the other element, or one or more intervening elements may be present. Furthermore, the connection/coupling may not be limited to a physical connection but may also include a non-physical connection, e.g., a wireless connection.

In addition, it will also be understood that when an element is referred to as being “between” two elements, it may be the only element between the two elements, or one or more intervening elements may also be present.

When a first element is referred to as being “over” a second element, it not only refers to a case where the first element is formed directly on the second element but also a case where a third element exists between the first element and the second element.

As used herein, singular forms are intended to include the plural forms as well, unless the context clearly indicates otherwise.

It should be understood that the drawings are simplified schematic illustrations of the described devices and may not include well known details for avoiding obscuring the features of the invention.

It should also be noted that features present in one embodiment may be used with one or more features of another embodiment without departing from the scope of the invention.

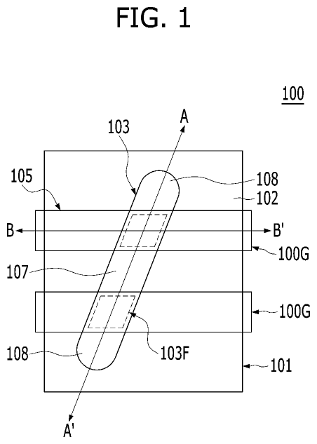

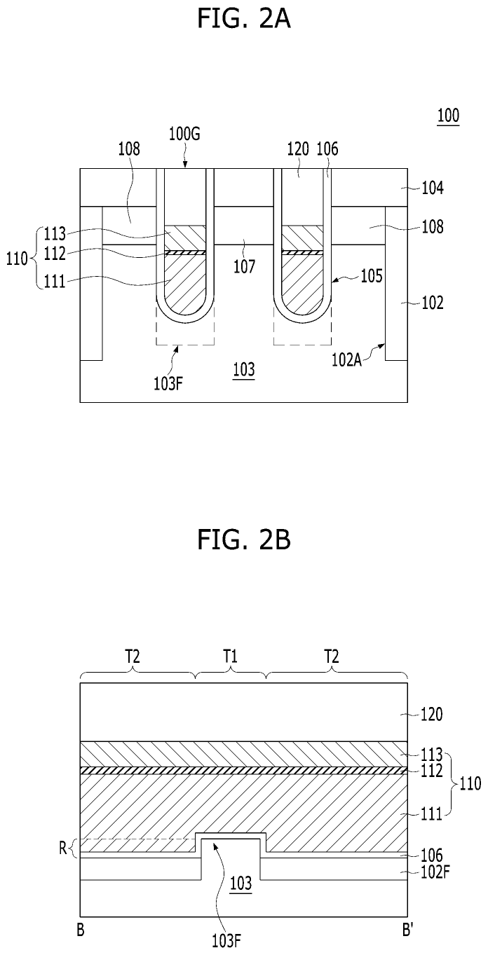

Referring now to FIG. 1, a plan view illustrating a semiconductor device is provided in accordance with an embodiment of the present invention. FIG. 2A is a cross-sectional view taken along a line A-A′ of FIG. 1. FIG. 2B is a cross-sectional view taken along a line B-B′ of FIG. 1.

Referring to FIGS. 1 to 2B, the semiconductor device 100 may include a substrate 101 and a buried gate structure 100G embedded in the substrate 101. The semiconductor device 100 may be part of a memory cell. For example, the semiconductor device 100 may be part of a memory cell of a Dynamic Random-Access Memory (DRAM).

The substrate 101 may be made of a material appropriate for semiconductor processing. The substrate 101 may include a semiconductor substrate. The substrate 101 may be formed of a silicon-containing material. The substrate 101 may include silicon, monocrystalline silicon, polysilicon, amorphous silicon, silicon germanium, monocrystalline silicon germanium, polycrystalline silicon germanium, carbon-doped silicon, a combination thereof, or a multi-layer thereof. The substrate 101 may include another semiconductor material, such as germanium. The substrate 101 may include a group III/V semiconductor substrate, which is a compound semiconductor substrate, such as GaAs. The substrate 101 may include a silicon on insulator (SOI) substrate.

An isolation layer 102 and an active region 103 may be formed in the substrate 101. The active region 103 may be defined by the isolation layer 102. The isolation layer 102 may be a shallow trench isolation region (STI) region formed by a trench etching process. The isolation layer 102 may be formed by filling a shallow trench, for example, an isolation trench 102A with a dielectric material such as, for example, silicon oxide, silicon nitride, or a combination thereof.

A trench 105 may be formed in the substrate 101. Referring to the plan view of FIG. 1, the trench 105 may have a shape of a line extending in one direction. The trench 105 may have a line shape traversing the active region 104 and the isolation layer 102. The trench 105 may have a shallower depth than the isolation trench 103. According to another embodiment of the present invention, the bottom portion of the trench 105 may have a curvature. The trench 105 may be a space in which a buried gate structure 100G is to be formed, and the trench 105 is referred to also herein as a ‘gate trench’.

A first doped region 107 and a second doped region 108 may be formed in the active region 103. The first doped region 107 and the second doped region 108 may be regions doped with a conductive dopant. For example, the conductive dopant may include phosphorus (P), arsenic (As), antimony (Sb), or boron (B). The first doped region 107 and the second doped region 108 may be doped with a dopant of the same conductivity type. In an embodiment, the first doped region 107 and the second doped region 108 may be doped with the same dopant. The first doped region 107 and the second doped region 108 may be positioned in the active region 103 on both sides of the trench 105. The bottom surfaces of the first doped region 107 and the second doped region 108 may be positioned at a predetermined depth from the top surface of the active region 103. In an embodiment, the bottom surfaces of the first doped region 107 and the second doped region 108 may be positioned at the same predetermined depth from the top surface of the active region 103. The first doped region 107 and the second doped region 108 may contact the sidewall of the trench 105. The bottom surfaces of the first doped region 107 and the second doped region 108 may be higher than the bottom surface of the trench 105. The first doped region 107 is also referred to herein as a ‘first source (or drain) region’, and the second doped region 108 is also referred to herein as a ‘second drain (or source) region’. A channel (not shown) may be defined between the first doped region 107 and the second doped region 108 by the buried gate structure 100G. The channel may be defined over the profile of the trench 105.

The trench 105 may include a first trench T1 and a second trench T2. The first trench T1 may be formed in the active region 103. The second trench T2 may be formed in the isolation layer 102. The trench 105 may continuously extend from the first trench T1 to the second trench T2. In the trench 105, the first trench T1 and the second trench T2 may have bottom surfaces positioned at different levels. For example, the bottom surface of the first trench T1 may be positioned at a higher level than the bottom surface of the second trench T2. The height difference between the first trench T1 and the second trench T2 may be formed as the isolation layer 102 is recessed. Accordingly, the second trench T2 may include a recess region R whose bottom surface is lower than the bottom surface of the first trench T1. Due to the step difference between the first trench T1 and the second trench T2, a fin region 103F may be formed in the active region 103. Therefore, the active region 103 may include the fin region 103F.

In this way, the fin region 103F may be formed below the first trench T1. A sidewall of the fin region 103F may be exposed by the recessed isolation layer 102F. The fin region 103F may be a portion where a part of the channel is formed. The fin region 103F is also referred to herein as a saddle fin. The fin region 103F may increase the channel width of the gate, thus improving the electrical characteristics of the device.

According to another embodiment of the present invention, the fin region 103F may be omitted.

The buried gate structure 100G may include a gate dielectric layer 106 that covers the bottom surface and the sidewall of the trench 105 and the sidewall of the hard mask layer 104, and a gate electrode 110 and a gate capping layer 120 that are sequentially stacked to fill the trench 105 over the gate dielectric layer 106. The gate electrode 110 may include a lower gate 111, a barrier layer 112, and an upper gate 113. The lower gate 111 may fill a lower portion of the trench 105 over the gate dielectric layer 106, and the barrier layer 112 and the upper gate 113 may fill a middle portion of the trench 105 over the lower gate 111. More specifically, the barrier layer 112 may be formed over the lower gate 111, and the upper gate 113 may be formed over the barrier layer 112. The gate capping layer 120 may fill an upper portion of the trench 105 over the upper gate 113. The lower portion, the middle portion and the upper portion of the trench 10 may be presented for convenience of description, and the heights (or depth) of the lower, middle and upper portions may be the same or different from each other. In the embodiment of FIG. 2A the thickness of the barrier layer 112 may be less than the thickness of the upper gate 113, and the thickness of the upper gate 113 may be less than the thickness of the lower gate 111.

The gate dielectric layer 106 may include, for example, silicon oxide. The gate dielectric layer 106 may include, for example, silicon oxide having a different wet etch rate from that of the hard mask layer 104. The gate dielectric layer 106 may be formed, for example, by an atomic layer deposition process in a furnace. In the process of forming the gate dielectric layer 106, the hard mask layer 104 may be hardened by heat. The gate dielectric layer 106 may include, for example, silicon oxide that is deposited at a temperature of at least approximately 500° C. or higher. The gate dielectric layer 106 may include, for example, silicon oxide that is deposited at a temperature of from approximately 500° C. to approximately 900° C. This is also referred to herein as a ‘HQ-oxide (High Quality Oxide) layer’.

The gate electrode 110 may be positioned at a lower level than the upper surface of the active region 103. In an embodiment, the upper surface of the gate electrode 110 may be positioned at a lower level than the upper surface of the active region 103. For example, the upper surface of the upper gate 113 may be at a lower level than the upper surface of the active region 103. The lower gate 111 may have a shape filling the bottom portion of the trench 105. The lower gate 111 may be formed of a low-resistance material to lower a gate sheet resistance. The lower gate 111 may be made of a metal-containing material. The lower gate 111 may include, for example, a metal, a metal nitride, or a combination thereof. The lower gate 111 may include tantalum nitride (TaN), titanium nitride (TiN), tungsten (W), tungsten nitride (WN), or a combination thereof. The lower gate 111 may be formed of titanium nitride alone. Also, the lower gate 111 may be formed of a stack of titanium nitride and tungsten (i.e., TiN/W).

According to another embodiment of the present invention, the lower gate 111 may have a high work function. Here, the high work function means a higher work function than a mid-gap work function of silicon. A low work function means a lower work function than the mid-gap work function of silicon. In other words, the high work function means a work function higher than approximately 4.5 eV, and the low work function means a work function lower than approximately 4.5 eV. The lower gate 111 may include, for example, P-type polysilicon or nitrogen-rich titanium nitride (TiN).

According to another embodiment of the present invention, the lower gate 111 may have an increased high work function. The lower gate 111 may include, for example, a metal silicon nitride. The metal silicon nitride may be a metal nitride doped with silicon. The lower gate 111 may include, for example, a metal silicon nitride whose silicon content is adjusted. For example, the lower gate 111 may include tantalum silicon nitride (TaSiN) or titanium silicon nitride (TiSiN). Titanium nitride has a high work function, and in order to further increase the work function of titanium nitride, silicon may be included in the titanium nitride. Particularly, in order to increase the high work function of titanium silicon nitride, the content of silicon may be adjusted. Herein, the content (atomic percent: at %) of silicon in the titanium silicon nitride may be equal to or less than approximately 21 at %. As a comparative example, in order to have a low work function, the content of silicon in the titanium silicon nitride may be approximately 30 at % or more.

The barrier layer 112 may include a metal-containing material. The barrier layer 112 may include a metal nitride. The barrier layer 112 may include, for example, titanium-nitride or tantalum nitride.

The upper gate 113 may be of a low resistance material to lower the gate sheet resistance. The upper gate 113 may be of a metal-containing material. The upper gate 113 may include a metal, a metal nitride, or a combination thereof. The upper gate 113 may include tantalum nitride (TaN), titanium nitride (TiN), tungsten, tungsten nitride, or a combination thereof. The upper gate 113 may be formed of titanium nitride alone. Also, the upper gate 113 may be formed of a stack of titanium nitride and tungsten (i.e., TiN/W).

In some embodiments, each of the lower gate 111, the barrier layer 112, and the upper gate 113 may be formed of titanium nitride alone. Also, each of the lower gate 111 and the upper gate 113 may be formed of a stack of titanium nitride and tungsten (TiN/W). Herein, the barrier layer 112 may be formed of titanium nitride just as the lower gate 111 is. The upper gate 113 may have a lower height than the lower gate 111, and accordingly, the volume of the lower gate 111 occupied in the trench 105 may be greater. The upper gate 113 may have a smaller width than the lower gate 111.

The gate capping layer 120 may serve to protect the upper gate 113. The gate capping layer 120 may fill the upper portion of the trench 105 over the upper gate 113. The upper surface of the gate capping layer 120 may be positioned at the same level as the upper surface of the hard mask layer 104. The gate capping layer 120 may include, for example, silicon nitride, silicon oxynitride, or a combination thereof. According to another embodiment of the present invention, the gate capping layer 120 may include a combination of silicon nitride and silicon oxide. The gate capping layer 120 may include a silicon nitride liner and a spin on dielectric material (SOD).

The hard mask layers 104 may be formed on both sides of the gate capping layer 120. The hard mask layer 104 may be a dielectric material. The hard mask layer 104 may include, for example, silicon oxide having a faster wet etch rate than the gate dielectric layer 106. The hard mask layer 104 may include low-temperature oxide. The hard mask layer 104 may be formed at a temperature of approximately 50° C. or lower. The hard mask layer 104 may include ULTO (Ultra Low Temperature Oxide). The hard mask layer 104 may be formed over the substrate 101 and may cover the active region 103 and the isolation layer 102.

As will be described later, the hard mask layer 104 may be hardened by heat when the gate dielectric layer 106 is formed. Alternatively, the hard mask layer 104 may be hardened through an oxidation process that proceeds after the gate dielectric layer 106 is formed.

Herein, the hard mask layer 104 whose film quality is hardened by heat may sufficiently serve as an etch barrier during a dry etching process, while the etch rate during a wet etching process is not different from the etch rate before the hardening (curing) because of the heat. Thus, the hard mask layer 104 may be readily removed by using a wet etching process.

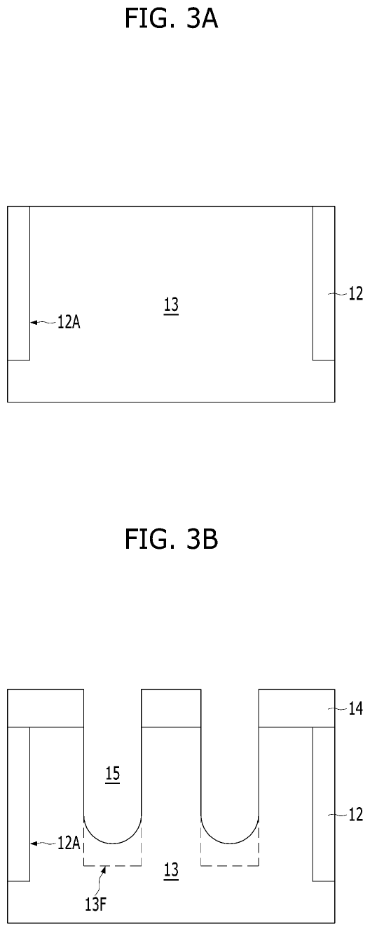

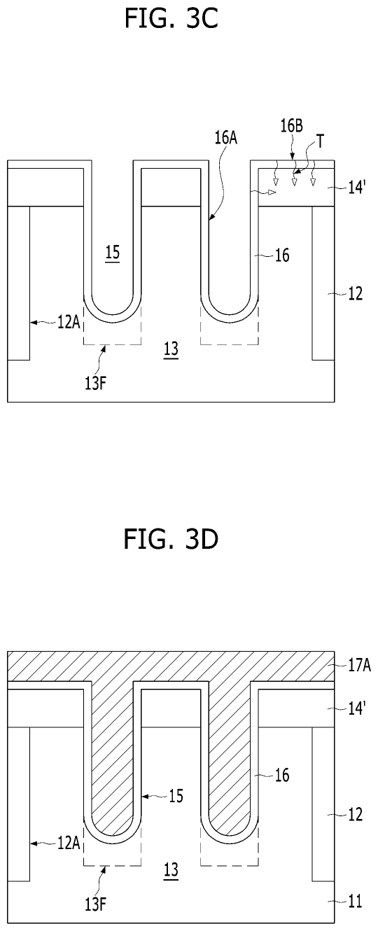

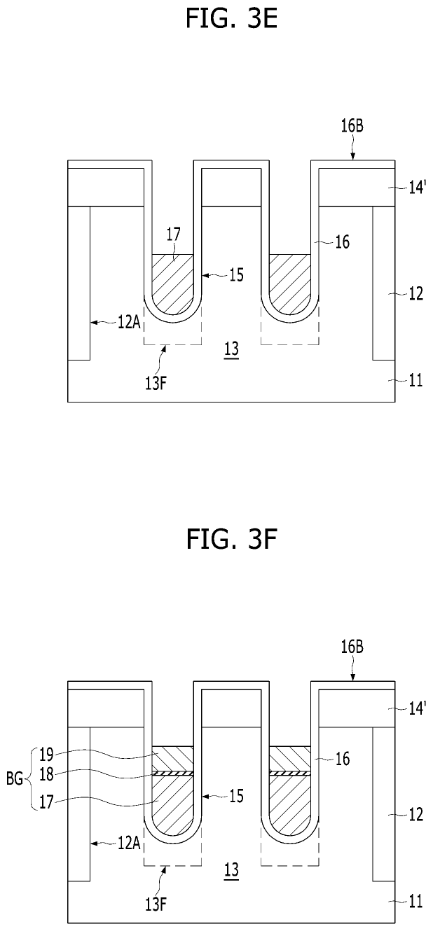

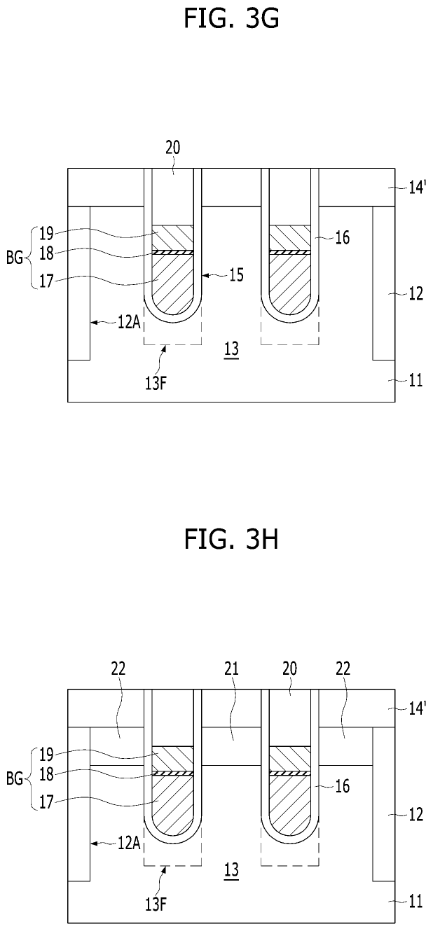

FIGS. 3A to 3H are cross-sectional views illustrating a method for fabricating a semiconductor device in accordance with a first embodiment of the present invention. FIGS. 3A to 3H illustrate a method for fabricating the semiconductor device 100 shown in FIG. 2A.

Referring to FIG. 3A, an isolation layer 12 may be formed in the semiconductor substrate 11. Active region 13 may be defined by the isolation layer 12.

The isolation layer 12 may be formed by a shallow trench isolation (STI) process. For example, an isolation trench 12A may be formed by etching the semiconductor substrate 11. Subsequently, the isolation trench 12A may be filled with a dielectric material, and as a result, the isolation layer 12 may be formed. The isolation layer 12 may include, for example, silicon oxide, silicon nitride, or a combination thereof. A chemical vapor deposition or any other suitable deposition process may be used to fill the isolation trench 12A with a dielectric material. Also, a planarization process, such as a chemical mechanical polishing (CMP) process, may be additionally used to fill only the isolation trench 12A with the dielectric material.

Referring to FIG. 3B, the hard mask layer 14 may be formed over the semiconductor substrate 11. The hard mask layer 14 may be formed to include a plurality of line-shaped openings. The openings may define a region in which gate electrodes are disposed.

The hard mask layer 14 may be formed to expose a portion of the active region 13 and a portion of the isolation layer 12. The hard mask layer 14 is also referred to herein as an etch mask. The hard mask layer 14 may be formed of a material having an etch selectivity with respect to the semiconductor substrate 11. The hard mask layer 14 may include, for example, silicon oxide. The hard mask layer 14 may include, for example, silicon oxide having a wet etch rate that is different from that of the gate dielectric layer which is formed by a subsequent process. In other words, the hard mask layer 14 may include, for example, silicon oxide, which has a faster wet etch rate than the gate dielectric layer. The hard mask layer 14 may include a low-temperature oxide. The hard mask layer 14 may be formed at a temperature of approximately 50° C. or lower. The hard mask layer 14 may be a silicon oxide, such as ULTO (Ultra-Low Temperature Oxide). A portion of the active region 13 may be exposed by the opening of the hard mask 14.

Subsequently, a plurality of trenches 15 may be formed. To form the trench 15, portions exposed by the hard mask 14 may be etched. That is, in order to form the trench 15, the exposed portion of the active region 13 and the exposed portion of the isolation layer 12 may be etched. The trench 15 may be formed shallower than the isolation trench 12A, however, the trench 15 may be formed to have a sufficient depth to adequately increase a surface area of the gate electrode which is formed subsequently in the trench 15. Accordingly, the resistance of the gate electrode may be reduced. The edge of the bottom portion of the trench 15 according to other embodiments of the present invention may have a curvature.

Subsequently, a fin region 13F may be formed. In order to form the fin region 13F, the isolation layer 12 below the trench 15 may be selectively recessed. As for the structure of the fin region 13F, the fin region 103F of FIG. 2B may be referred to.

Referring to FIG. 3C, a gate dielectric layer 16 may be formed by hardening a hard mask layer 14′. The gate dielectric layer 16 may be formed over the profile of the semiconductor substrate 11 including the trench 15. In other words, the gate dielectric layer 16 may be formed to cover the bottom surface and the sidewalls of the trench 15 and the sidewalls and upper surface of the hard mask layer 14′. The gate dielectric layer 16 may include a first portion 16A covering the bottom surface and the sidewalls of the trench 15 and a second portion 16B covering the hard mask layer 14′. The first portion 16A and the second portion 16B of the gate dielectric layer 16 may be in continuum. The second portion 16B of the gate dielectric layer 16 may function as a passivation layer covering the hard mask layer 14′. Hereinafter, the second portion 16B of the gate dielectric layer 16 will be referred to as a ‘passivation layer 16B’.

The gate dielectric layer 16 may include, for example, silicon oxide. The gate dielectric layer 16 may include, for example, silicon oxide having a slower wet etch rate than the hard mask layer 14′. The gate dielectric layer 16 may include a high-temperature oxide. The gate dielectric layer 16 may be deposited by an atomic layer deposition process in a furnace. The gate dielectric layer 16 may include, for example, silicon oxide which is deposited by an atomic layer deposition process at a temperature of approximately 500° C. or higher (e.g., from approximately 500° C. to approximately 900° C.). This is also referred to herein as a ‘HQ-oxide (High Quality Oxide) layer’.

By forming the gate dielectric layer 16 through a deposition process, silicon loss of the active region 13 may be prevented. Therefore, it is possible to prevent the deterioration of the critical dimension and bending of the active region 13.

Also, as the gate dielectric layer 16 is formed, for example, by an atomic layer deposition method, step coverage may be excellent. Moreover, since the gate dielectric layer 16 including a HQ-oxide is deposited at a temperature of approximately 500° C. or higher, the film quality may be harder and denser than the film quality of an oxide layer which is deposited at a general atomic layer deposition temperature of approximately 200° C. to 400° C. Accordingly, it may serve as a passivation layer that prevents damage of the hard mask layer 14′ in the subsequent process.

Also, the hard mask layer 14′ hardened by heat T may be reformed into hardened silicon oxide. Therefore, the loss of the hard mask layer 14′ may be prevented during a subsequent recessing process of the gate layer. In other words, even though the hard mask layer 14′ may be exposed due to damage of the gate dielectric layer 16 in an etch-back process for forming the gate electrode, the damage may be minimized. Meanwhile, the hard mask layer 14′ whose film quality is hardened (e.g., by heat) may sufficiently serve as an etch barrier during a dry etching process, and since the etch rate during a wet etching process is not different from that before the hardening, it may be easily removed.

Referring to FIG. 3D, a gate layer 17A may be formed over the gate dielectric layer 16. The gate layer 17A may be formed to fill the trench 15 over the gate dielectric layer 16. The gate layer 17A may be formed over the profile of the semiconductor substrate 11 including the trench 15. In order to lower the resistance of the gate electrode, the gate layer 17A may include a low resistance metal. For example, the gate layer 17A may include tungsten (W), titanium nitride (TiN), or a combination thereof.

According to another embodiment of the present invention, the gate layer 17A may include a high work function material. The gate layer 17A may include a high work function metal or a high work function polysilicon. The high work function polysilicon may include, for example, P-type polysilicon. The high work function metal may include, for example, nitrogen-rich titanium nitride (TiN).

Referring to FIG. 3E, a lower gate 17 may be formed inside the second trench 15. In order to form the lower gate 17, a recessing process may be performed. The recessing process may be performed by a dry etching process, for example, an etch-back process. The etch-back process may be performed using plasma.

According to another embodiment of the present invention, the recessing process may be performed by performing a planarization process first to expose the passivation layer 16B in the upper portion of the hard mask layer 14′ and then performing an etch-back process.

As described above, during the recessing process, as the film quality of the hard mask layer 14′ is reformed into a hardened silicon oxide along with the passivation layer 16B in the upper portion, the hard mask layer 14′ may not be damaged and may maintain the width and thickness before the recessing process.

Referring to FIG. 3F, a barrier layer 18 and an upper gate 19 may be further formed over the lower portion gate 17.

The barrier layer 18 may be formed by performing a nitridation process on the surface of the lower portion gate 17. The barrier layer 18 may include, for example, titanium-nitride.

The upper gate 19 may be formed through a series of processes for forming a gate layer (not shown) to fill the trench 15 over the barrier layer 18 and then performing a recessing process. The recessing process may be performed by a dry etching process, for example, an etch-back process. The etch-back process may be performed using plasma.

According to another embodiment of the present invention, the recessing process may be performed by performing a planarization process first to expose the gate dielectric layer 16 of the upper portion of the hard mask layer 14′, and then performing an etch-back process subsequently.

As described above, during the recessing process, as the film quality of the hard mask layer 14′ is reformed into a hardened silicon oxide along with the passivation layer 16B of the upper portion, the hard mask layer 14′ may not be damaged and may maintain the width and thickness before the recessing process.

The upper gate 19 may include a low resistance material. The upper gate 19 may be formed of the same material as that of the lower gate 17. The upper gate 19 may include a metal-containing material including, for example, a metal, a metal nitride, or a combination thereof. The upper gate 19 may include, for example, tungsten, tungsten nitride, titanium nitride, or a combination thereof. According to another embodiment of the present invention, the upper gate 19 may include a low work function metal or a low work function polysilicon.

Accordingly, a buried gate electrode BG in which the lower gate 17, the barrier layer 18, and the upper gate 19 are stacked may be formed. When the lower gate 17, the barrier layer 18 and the upper gate 19 are formed of a metal-based material, the volume of the metal-containing material occupying in the buried gate electrode BG may be increased. Accordingly, the resistance of the buried gate electrode BG may be lowered.

Referring to FIG. 3G, a gate capping layer 20 may be formed over the upper gate 19. The gate capping layer 20 may include a dielectric material. The gate capping layer 20 may include, for example, silicon nitride. The gate capping layer 20 may have an oxide-nitride-oxide (ONO) structure according to an implementation of the described embodiment.

Subsequently, the gate capping layer 20 may be planarized to expose the upper surface of the hard mask layer 14′ while the gate capping layer 20 filling the trench 15 may remain in the trench 15. The planarization may be performed, for example, by a chemical mechanical polishing (CMP) process or an etch-back process. Also, the passivation layer 16B (see FIG. 3F) may be removed by the planarization process while the gate dielectric layer 16 covering the bottom surface and the sidewalls of the trench 15 remain.

The bottom surface of the gate capping layer 20 may contact the upper surface of the upper gate 19. Both sidewalls of the gate capping layer 20 may contact the gate dielectric layer 16.

A buried gate structure may be formed by a series of the processes as described above. The buried gate structure may include the gate dielectric layer 16, the buried gate electrode BG, and the gate capping layer 20. The buried gate electrode BG may include the lower gate 17, the barrier layer 18, and the upper gate 19. The upper surface of the upper gate 19 may be positioned lower than the upper surface of the active region 13.

Referring now to FIG. 3H, a first doped region 21 and a second doped region 22 may be formed in the active region 13. The first doped region 21 and the second doped region 22 may be formed by an impurity doping process, such as an implantation process or other doping techniques. The first doped region 21 may be formed between two adjacent buried gate electrodes BGs. The first doped region 21 is also referred to herein as a first source or drain region. The second doped region 22 may be formed between the isolation layer 12 and the buried gate electrode BG. The second doped region 22 is also referred to herein as a second source or drain region.

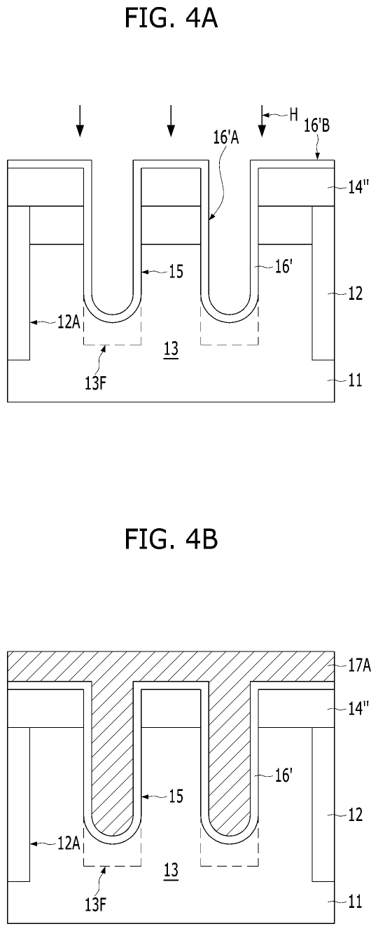

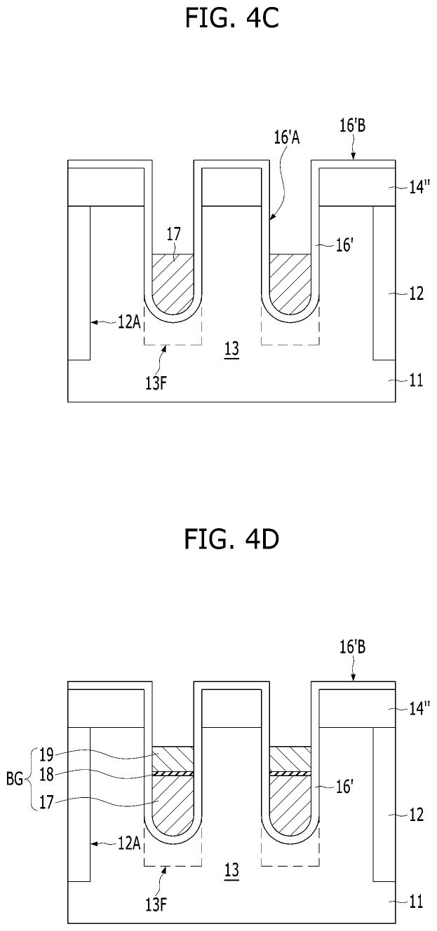

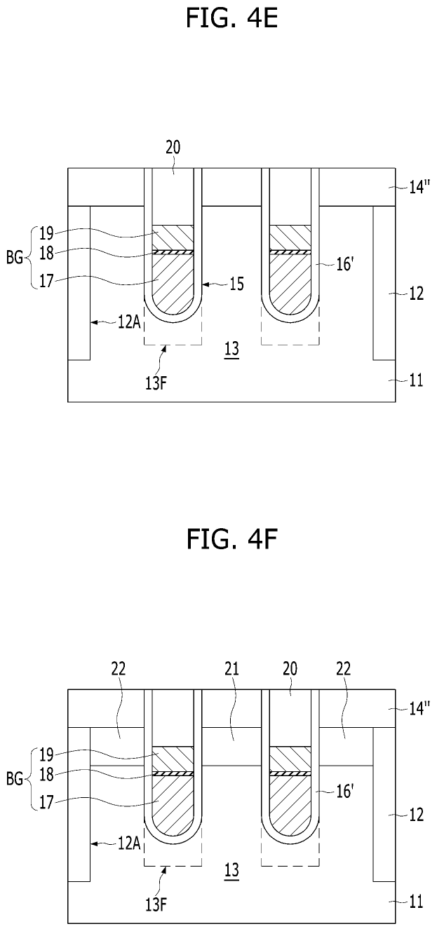

FIGS. 4A to 4F are cross-sectional views illustrating a method for fabricating a semiconductor device in accordance with a second embodiment of the present invention.

Referring to FIG. 4A, an isolation layer 12 which defines an active region 13, a hard mask layer 14″, and a plurality of trenches 15 may be formed in the semiconductor substrate 11. These may be formed through the same processes as the ones described in reference with FIGS. 3A to 3C.

Subsequently, an oxidation process may be performed to form a hardened gate dielectric layer 16′ and a hardened hard mask layer 14″. Hereinafter, the hardened gate dielectric layer 16′ is also referred to herein as a gate dielectric layer 16′. The hardened hard mask layer 14″ is also referred to herein as a hard mask layer 14″. The part of the gate dielectric layer 16′ that is positioned over the hard mask layer 14″ is also referred to herein as a passivation layer 16′B.

The oxidation process may be performed in-situ in the same chamber employed in the gate dielectric layer 16 (see FIG. 3C) formation process. The oxidation process may be performed at the same temperature as that of the gate dielectric layer (see FIG. 3C) formation process. According to another embodiment of the present invention, the oxidation process may be performed ex-situ in the same chamber employed in the gate dielectric layer 16 (see FIG. 3C) formation process. The oxidation process may be performed at a higher temperature than the temperature employed in the gate dielectric layer 16 (see FIG. 3C) formation process.

According to the oxidation process, the gate dielectric layer 16′ and the hard mask layer 14″ may be hardened to have improved film quality. Therefore, the hard mask layer 14″ and the sidewall of the trench 15 may be more effectively prevented from being damaged during the subsequent recessing process.

Referring to FIG. 4B, a gate layer 17A may be formed over the gate dielectric layer 16′. The gate layer 17A may be formed to fill the trench 15 over the gate dielectric layer 16′. The gate layer 17A may be formed over the profile of the semiconductor substrate including the trench 15. In order to lower the resistance of the gate electrode, the gate layer 17A may include a low resistance metal. For example, the gate layer 17A may include tungsten (W), titanium nitride (TiN), or a combination thereof.

According to another embodiment of the present invention, the gate layer 17A may include a high work function material. The gate layer 17A may include a high work function metal or a high work function polysilicon. The high work function polysilicon may include, for example, P-type polysilicon. The high work function metal may include, for example, nitrogen-rich titanium nitride (TiN).

Referring to FIG. 4C, a lower gate 17 may be formed inside the trench 15. The lower gate 17 may be formed using a recessing process. The recessing process may be a dry etching process, for example, an etch-back process. The etch-back process may be performed using plasma.

According to another embodiment of the present invention, the recessing process may include a planarization process first to expose the passivation layer 16′B in the upper portion of the hard mask layer 14″ and then performing the etch-back process.

As described above, during the recessing process, the hard mask layer 14″ may not be damaged and may maintain the width and thickness it had before the recessing process, because as described earlier the film quality of the hard mask layer 14″ is reformed in a hardened silicon oxide together with the passivation layer 16′B of the upper portion.

Referring to FIG. 4D, a barrier layer 18 and an upper gate 19 may be further formed over the lower gate 17.

The barrier layer 18 may be formed on top of the upper surface of the lower gate 17 by performing a nitridation process on the upper surface of the lower gate 17. The barrier layer 18 may include, for example, titanium-nitride.

The upper gate 19 may be formed through a series of processes including forming a gate layer (not shown) to fill the trench 15 over the barrier layer 18 and then performing a recessing process. The recessing process may be a dry etching process, for example, an etch-back process. The etch-back process may be performed using plasma.

According to another embodiment of the present invention, the recessing process may include a planarization process which is performed first to expose the second portion 16′B of an H-gate dielectric layer in the upper portion of the hard mask layer 14 and then performing an etch-back process subsequently.

As described above, during the recessing process, the hard mask layer 14″ may not be damaged and may maintain the width and thickness it had before the recessing process, as the film quality of the hard mask layer 14″ is reformed into a hardened silicon oxide together with the passivation layer 16′B of the upper portion.

The upper gate 19 may include a low resistance material. The upper gate 19 may be formed of the same material as that of the lower gate 17. The upper gate 19 may include a metal-containing material. The upper gate 19 may include a metal, a metal nitride, or a combination thereof. The upper gate 19 may include, for example, tungsten, tungsten nitride, titanium nitride, or a combination thereof. According to another embodiment of the present invention, the upper gate 19 may include a low work function metal or a low work function polysilicon.

Accordingly, a buried gate electrode BG in which the lower gate 17, the barrier layer 18, and the upper gate 19 are stacked may be formed. When the lower gate 17, the barrier layer 18 and the upper gate 19 are formed of a metal-containing material, the volume of the metal-containing material occupying in the buried gate electrode BG may be increased. Accordingly, the resistance of the buried gate electrode BG may be lowered.

Referring to FIG. 4E, a gate capping layer 20 may be formed over the upper gate 19. The gate capping layer 20 may include a dielectric material. The gate capping layer 20 may include, for example, silicon nitride. The gate capping layer 20 may have an oxide-nitride-oxide (ONO) structure according to an implementation of the described embodiment.

Subsequently, the gate capping layer 20 may be planarized to expose the upper surface of the hard mask layer 14″ while the gate capping layer 20 filling the trench 15 may remain in the trench 15. The planarization may be performed by a chemical mechanical polishing (CMP) process or an etch-back process. Also, the passivation layer 16′B may be removed by a planarization process, and a gate dielectric layer 16′ covering the bottom surface and the sidewalls of the trench 15 may remain.

The bottom surface of the gate capping layer 20 may contact the upper surface of the upper gate 19. Both sidewalls of the gate capping layer 20 may contact the gate dielectric layer 16′.

A buried gate structure is formed by a series of the processes as described above. The buried gate structure may include the gate dielectric layer 16′, the buried gate electrode BG, and the gate capping layer 20. The buried gate electrode BG may include the lower gate 17, the barrier layer 18, and the upper gate 19. The upper surface of the upper gate 19 may be positioned lower than the upper surface of the active region 13.

Referring to FIG. 4F, the first doped region 21 and the second doped region 22 may be formed in the active region 13. The first doped region 21 and the second doped region 22 may be formed by an impurity doping process, by an implantation process or other doping techniques. The first doped region 21 may be formed between two adjacent buried gate electrodes BG. The first doped region 21 is also referred to herein as a first source or drain region. The second doped region 22 may be formed between the isolation layer 12 and the buried gate electrode BG. The second doped region 22 is also referred to herein as a second source or drain region.

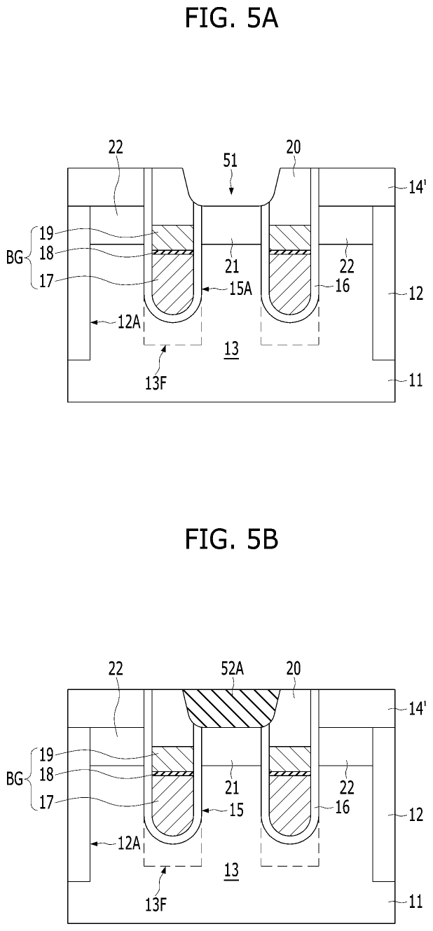

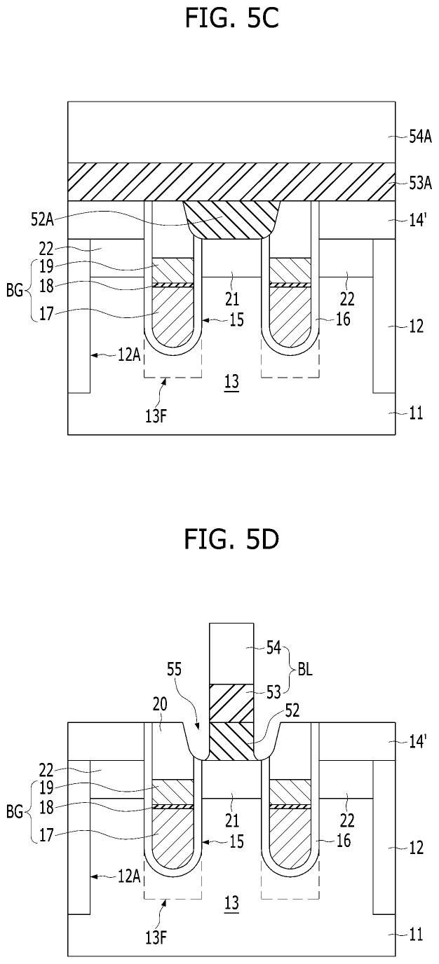

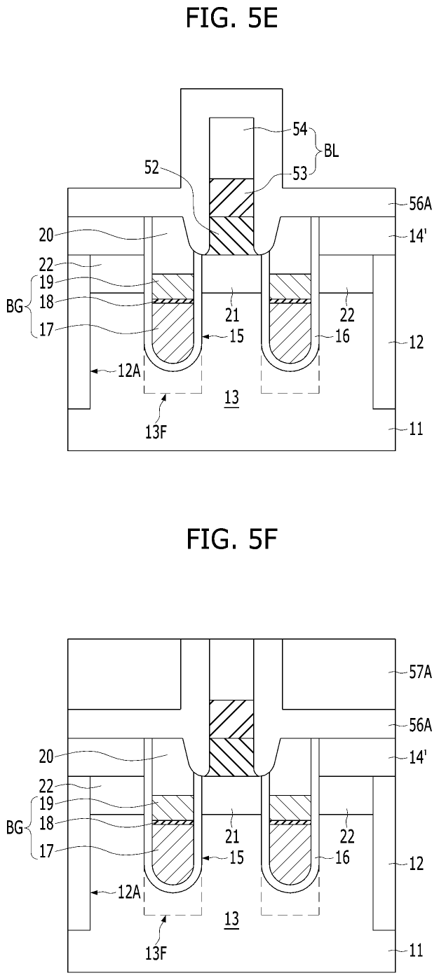

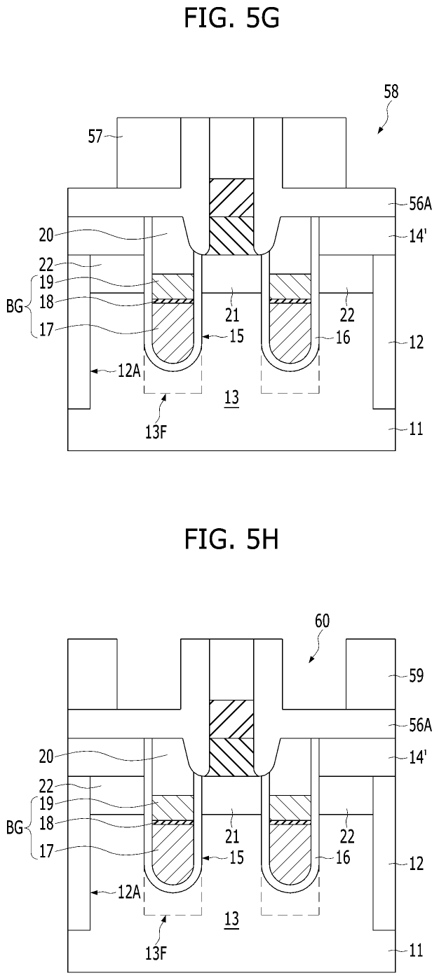

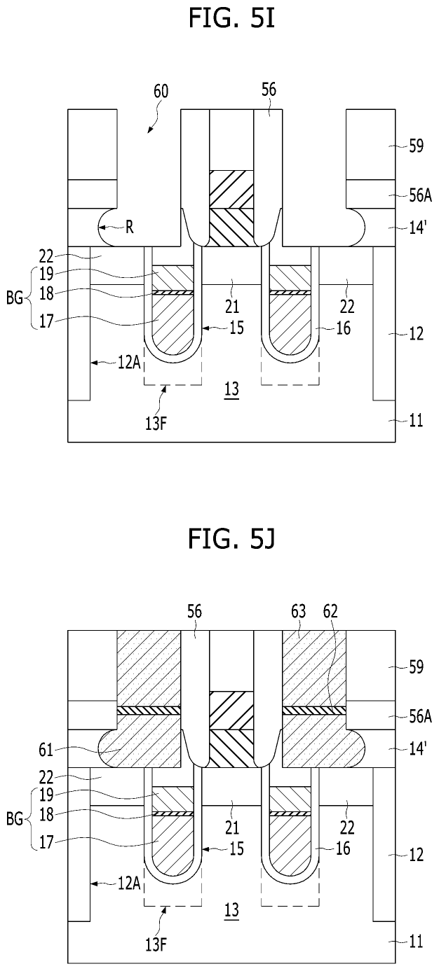

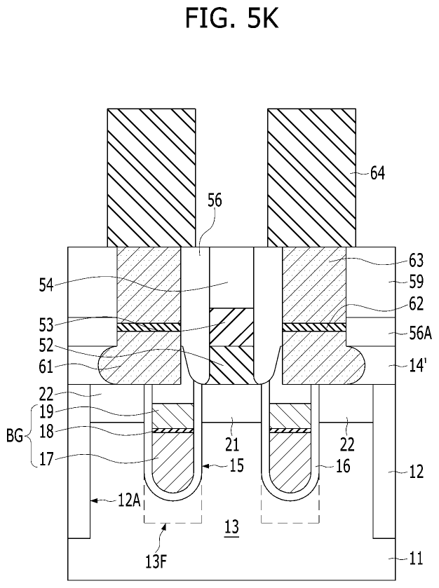

FIGS. 5A to 5K are cross-sectional views illustrating a method for fabricating a memory cell in accordance with embodiments of the present invention.

Referring to FIG. 5A, a first contact hole 51 may be formed. For example, a hard mask layer 14′ may be etched by using a contact mask (not shown) to form the first contact hole 51. The first contact hole 51 may have a circle shape or an ellipse shape when viewed from the perspective of a plan view. A portion of the active region 13 may be exposed by the first contact hole 51. The first contact hole 51 may have a diameter that is adjusted by a predetermined line width. For example, the first doped region 21 may be exposed by the first contact hole 51. The first contact hole 51 may have a larger diameter than the width of the short axis of the active region 13. Therefore, the first doped region 21 and a portion of the gate capping layer 20 may be etched in the etching process for forming the first contact hole 51. In other words, the first doping region 21 and the gate capping layer 20 below the first contact hole 51 may be recessed to a predetermined depth. As a result, the bottom portion of the first contact hole 51 may be expanded.

Referring to FIG. 5B, a preliminary plug 52A may be formed. The method for forming the preliminary plug 52A is as follows. First, a first conductive layer (not shown) for filling the first contact hole 51 may be formed over the profile of the semiconductor substrate 11 including the first contact hole 51. Subsequently, the first conductive layer may be etched to expose the surface of the hard mask layer 14′. As a result, the preliminary plug 52A filling the first contact hole 51 may be formed. The upper surface of the preliminary plug 52A may be coplanar with the upper surface of the hard mask layer 14′. In another implementation of the embodiment (not shown), the upper surface of the preliminary plug 52A may be lower than the surface of the hard mask layer 14′. Subsequently, the preliminary plug 52A may be doped with an impurity using any suitable doping process, such as, for example, an implantation process.

Referring to FIG. 5C, a second conductive layer 53A and a bit line capping layer 54A may be stacked. The second conductive layer 53A and the bit line capping layer 54A may be sequentially stacked over the preliminary plug 52A and the hard mask layer 14′. The second conductive layer 53A may include a metal-containing material. The second conductive layer 53A may include a metal, a metal nitride, a metal silicide, or a combination thereof. In this embodiment of the present invention, the second conductive layer 53A may include tungsten (W). According to another embodiment of the present invention, the second conductive layer 43A may include a stack of titanium nitride and tungsten (TiN/W). Herein, the titanium nitride may serve as a barrier. The bit line capping layer 54A may be formed of a dielectric material having an etch selectivity with respect to the second conductive layer 53A and the preliminary plug 52A. The bit line capping layer 54A may include, for example, silicon oxide or silicon nitride.

Referring to FIG. 5D, a bit line structure BL and a bit line contact plug 52 may be formed. The bit line structure BL and the bit line contact plug 52 may be formed by an etching process using a bit line mask (not shown). The bit line capping layer 54A (see FIG. 5C) and the second conductive layer 53A (see FIG. 5C) may be etched by using the bit line mask (not shown) as an etch barrier. Accordingly, a bit line structure BL including a bit line 53 and a bit line capping layer 54 may be formed. The bit line 53 may be formed by etching the second conductive layer 53A. The bit line capping layer 54 may be formed by etching the bit line capping layer 54A. In an embodiment, the bit line capping layer 54 may be formed directly over the bit line 53.

Subsequently, the preliminary plug 52A (see FIG. 5C) may be etched with the same line width as that of the bit line 53. As a result, the bit line contact plug 52 may be formed so that the bit line may be directly over the bit line contact plug 52. The bit line contact plug 52 may be formed over the first doped region 21. The bit line contact plug 52 may interconnect the first doped region 21 and the bit line 53 to each other. The bit line contact plug 52 may be formed in the first contact hole 51. The diameter of the bit line contact plug 52 may be smaller than the diameter of the first contact hole 51. Accordingly, a gap 55 may be formed around the bit line contact plug 52.

Referring to FIG. 5E, a spacer element 56A may be formed. The spacer element 56A may be positioned on the sidewalls of the bit line contact plug 42 and the bit line structure BL. The spacer element 56A may be formed of a plurality of spacers or spacer portions. In an embodiment, the plurality of spacers (or spacer portions) may be continuous, forming a single continuous spacer structure (or spacer element) 56A. The spacer element 56A may be formed of any suitable material. The spacer element 56A may be formed, for example, of silicon oxide, silicon nitride, or a combination thereof. A spacer portion of the spacer element 56A may fill the gap 55 (see FIG. 5D).

Referring to FIGS. 5F to 5H, a sacrificial layer 57A may be formed between the bit line structures BL. The sacrificial layer 57A may include an oxide. For example, the sacrificial layer 57A may include a spin on dielectric (SOD) or BPSG. The sacrificial layer 57A may be formed through a planarization process in which the upper surface of the bit line structure BL is exposed, after gap-filling the space between the bit line structures BL with the oxide. During the planarization process, a portion of the spacer element 56A formed on the upper surface of the bit line structure BL may be removed.

Subsequently, a plug isolation layer 59 and a second contact hole 60 may be formed. The plug isolation layer 59 may gap-fill the space between the bit line structures BL. The plug isolation layer 59 may include, for example, silicon nitride. A damascene process may be applied to form the second contact hole 60. For example, a plug isolation portion 58 may be formed by filling the space between the bit line structures BL with the sacrificial layer 57A and then etching a portion of the sacrificial layer 57A.

Subsequently, the plug isolation portion 58 may be filled with the plug isolation layer 59. Subsequently, the second contact hole 60 may be formed by removing the remaining sacrificial layer 57. For example, the plug isolation layer 59 may be formed by forming silicon nitride and then planarizing the formed silicon nitride. A dip-out process may be applied to remove the sacrificial layer 57. From the perspective of a plan view, the second contact hole 60 may have a rectangular shape.

Referring to FIG. 51, an etching process may be performed to expose the second doped region 22. This is also referred to herein as a widening process of the second contact hole 60. For example, a spacer 56 may be formed on the sidewall of the bit line structure BL by etching the spacer element 56A in the second contact hole 60.

Subsequently, the hard mask layer 14′ may be etched by self-aligning the spacer 56. The bottom portion of the second contact hole 60 may be widened by the widening process, and the second doped region 22 may be exposed. Subsequently, the second doped region 22 and a portion of the gate capping layer 20 may be recessed to a predetermined depth. The bottom portion of the second contact hole 60 may have a round profile (refer to R) due to the difference in the etch selectivity. The contact area of the storage node contact plug to be formed subsequently therein may be increased by the round profile R.

The widening process of the second contact hole 60 may proceed in a lateral direction as well as a depth direction. To this end, an isotropic etching process may be performed. The hard mask layer 14′ may be etched isotropically by the isotropic etching process.

In the embodiments of the present invention, since the loss of the hard mask layer 14′ does not occur during the formation of the buried gate electrode BG, the gap for electrically insulating the neighboring second contact holes 60 from each other during the widening process may be secured sufficiently.

Referring to FIG. 5J, a silicon plug 61 partially filling the second contact hole 60 may be formed. In order to form the silicon plug 61, a polysilicon layer may be formed to fill the second contact hole 60. Subsequently, the polysilicon layer may be recessed to have an upper surface that is lower than the upper surface of the bit line structure BL. As a result, the silicon plug 61 may be formed in the second contact hole 60. The silicon plug 61 is also referred to herein as a ‘polysilicon plug’. The silicon plug may be doped with a dopant.

Subsequently, a metal silicide 62 may be formed by a silicide-metal layer deposition process and a thermal process. The metal silicide 62 may be formed over the upper surface of the silicon plug 61. After the thermal process, the unreacted silicide-metal layer may be removed.

The metal silicide 62 may include cobalt silicide, but the concept and spirit of the present invention are not limited to cobalt silicide. For example, the metal silicide may be formed by using another metal (for example, titanium, nickel, etc.) that may react with silicon to form a silicide.

A conductive layer may fill the remainder of the second contact hole 60 over the upper surface of the metal silicide layer 62. The conductive layer may be a material having a lower resistance than the silicon plug 61. For example, the conductive layer may be a metal material. After filling the second contact hole 60 with the conductive layer, a Chemical Mechanical Polishing (CMP) process may be performed. As a result, the metal plug 63 may be formed in the second contact hole 60.

As a result of what is described above, a storage node contact plug may be formed. The storage node contact plug may include a silicon plug 61, a metal silicide 62, and a metal plug 63.

Referring to FIG. 5K, a memory element may be formed over the metal plug 63. The memory element may include a capacitor including a storage node 64. Although not illustrated, a dielectric layer and a plate node may be formed over the storage node 64. The storage node 64 may have a pillar shape. The storage node 64 may have a cylinder shape according to another embodiment of the present invention.

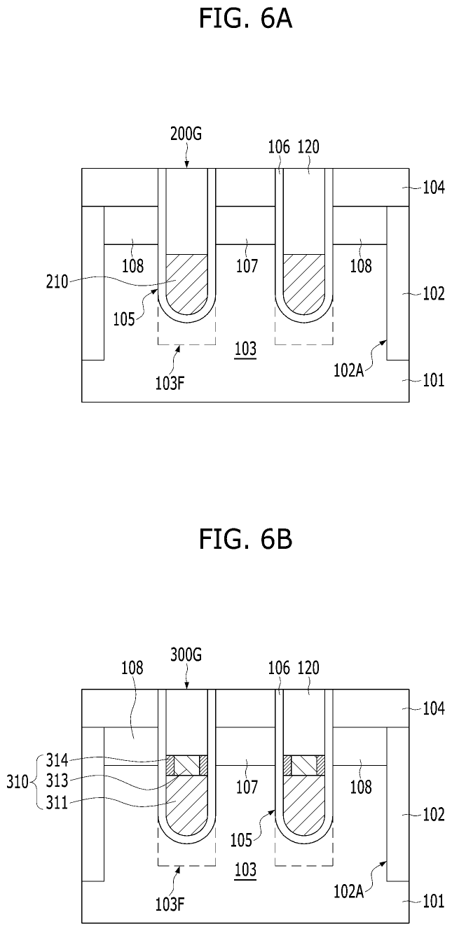

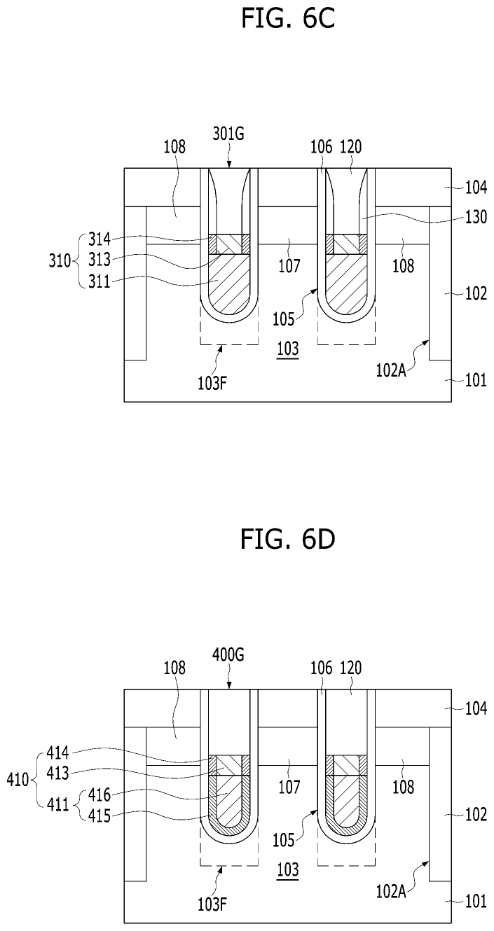

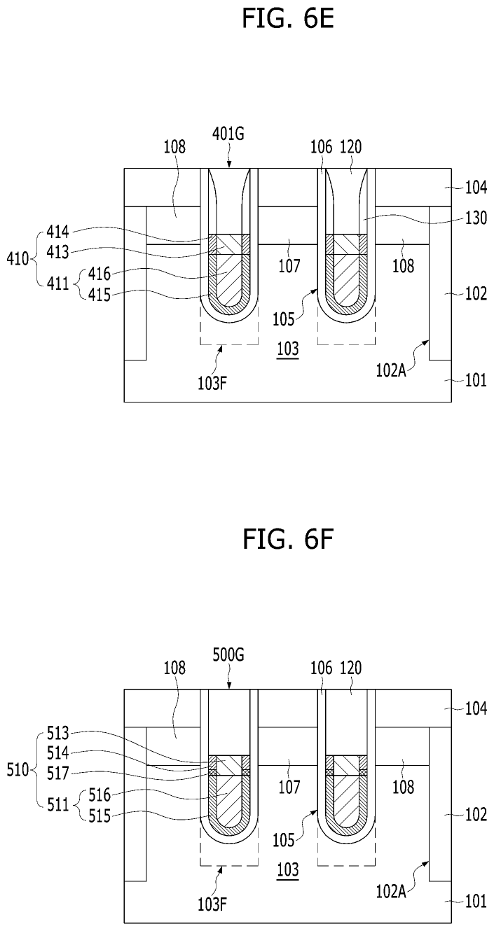

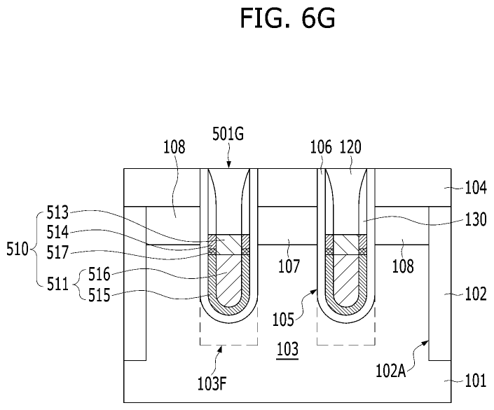

FIGS. 6A to 6G are cross-sectional views illustrating semiconductor devices in accordance with other embodiments of the present invention. The semiconductor devices shown in FIGS. 6A to 6G may have similar constituent elements to those of the semiconductor device 100 of FIG. 2A, except for the buried gate structures 200G to 501G. Hereinafter, detailed description of the overlapping constituent elements may be omitted.

Referring to FIG. 6A, the semiconductor device may include a buried gate structure 200G, a first doped region 107, and a second doped region 108. An isolation layer 102 and an active region 103 may be formed in the substrate 101. Also, a trench 105 crossing the active region 103 and the isolation layer 102 may be formed. A buried gate structure 200G may be formed in the trench 105. A channel may be formed between the first doped region 107 and the second doped region 108 by the buried gate structure 200G. The channel may be defined according to the profile of the trench 105.

The buried gate structure 200G may be disposed inside the trench 105. The buried gate structure 200G may be disposed in the active region 103 between the first doped region 107 and the second doped region 108 and extend into the isolation layer 102. A fin region 103F may be positioned in the active region 103 below the buried gate structure 200G.

The buried gate structure 200G may include a gate dielectric layer 106 that covers the bottom surface and the sidewalls of the trench 105, a gate electrode 210 and a gate capping layer 120. The gate electrode 210 and the gate capping layer 120 may be sequentially stacked to fill the trench 105 over the gate dielectric layer 106.

The gate electrode 210 may be formed as a single gate electrode. The gate electrode 210 may be a low resistance material.

The gate electrode 210 may be a metal-containing material. The gate electrode 210 may include a metal, a metal nitride, or a combination thereof. The gate electrode 210 may have a high work function. The gate electrode 210 may include, for example, P-type polysilicon or nitrogen-rich titanium nitride. The gate electrode 210 may include, for example, a metal silicon nitride.

Referring to FIG. 6B, the semiconductor device may include a buried gate structure 300G, a first doped region 107, and a second doped region 108. An isolation layer 102 and an active region 103 may be formed in the substrate 101. Also, a trench 105 crossing the active region 103 and the isolation layer 102 may be formed. A buried gate structure 300G may be formed in the trench 105. A channel may be formed between the first doped region 107 and the second doped region 108 by the buried gate structure 300G. The channel may be defined according to the profile of the trench 105.

A buried gate structure 300G may be disposed in the trench 105. The buried gate structure 300G may be disposed in the active region 103 between the first doped region 107 and the second doped region 108 and extend into the isolation layer 102. A fin region 103F may be positioned in the active region 103 below the buried gate structure 300G.

The buried gate structure 300G may include a gate dielectric layer 106 that covers the bottom surface and the sidewalls of the trench 105, a gate electrode 310 and a gate capping layer 120 formed over the gate dielectric layer 106 to fill the trench 105.

The gate electrode 310 may include a lower gate 311, an upper gate 313, and a vertical gate 314. The lower gate 311 and the upper gate 313 may correspond to the lower gate 111 and the upper gate 113 shown in FIG. 2A.

The vertical gate 314 may cover both sides of the upper gate 313. The vertical gate 314 may be positioned between the upper gate 313 and the gate dielectric layer 106. The vertical gate 314 may extend vertically from the upper portion edge surfaces on both sides of the lower gate 311. The vertical gate 314 may have a lower workfuction than the lower gate 311. The vertical gate 314 may include a low work function metal or N-type polysilicon.

Referring to FIG. 6C, the semiconductor device may include a buried gate structure 301G, a first doped region 107, and a second doped region 108. An isolation layer 102 and an active region 103 may be formed in the substrate 101. Also, a trench 105 crossing the active region 103 and the isolation layer 102 may be formed. The buried gate structure 301G may be formed in the trench 105. A channel may be formed between the first doped region 107 and the second doped region 108 by the buried gate structure 301G. The channel may be defined according to the profile of the trench 105.

The buried gate structure 301G may be disposed in the trench 105. The buried gate structure 301G may be disposed in the active region 103 between the first doped region 107 and the second doped region 108 and extend into the isolation layer 102. A fin region 103F may be positioned in the active region 103 below the buried gate structure 301G.

The buried gate structure 301G may include a gate dielectric layer 106 that covers the bottom surface and the sidewalls of the trench 105, a gate electrode 310 and a gate capping layer 120. The gate electrode 310 and the gate capping layer 120 may be sequentially stacked over the gate electrode to fill the trench 105 over the gate dielectric layer 106. The buried gate structure 301G may further include a spacer 130 between the gate capping layer 120 and the gate dielectric layer 106.

The gate electrode 310 may include a lower gate 311, an upper gate 313, and a vertical gate 314. The spacer 130 may directly contact the upper portion of the vertical gate 314. The spacer 130 may cover a portion of the gate dielectric layer 106.

The sidewall of the spacer 130 and the sidewall of the vertical gate 314 may be self-aligned. The spacer 130 may include a dielectric material. The spacer 130 may include an oxide. The spacer 130 may include CFD oxide or ULTO.

Referring to FIG. 6D, the semiconductor device may include a buried gate structure 400G, a first doped region 107, and a second doped region 108. An isolation layer 102 and an active region 103 may be formed in the substrate 101. Also, a trench 105 crossing the active region 103 and the isolation layer 102 may be formed. A buried gate structure 400G may be formed in the trench 105. A channel may be formed between the first doped region 107 and the second doped region 108 by the buried gate structure 400G. The channel may be defined according to the profile of the trench 105.

The buried gate structure 400G may be disposed in the trench 105. The buried gate structure 400G may be disposed in the active region 103 between the first doped region 107 and the second doped region 108 and extend into the isolation layer 102. A fin region 103F may be positioned in the active region 103 below the buried gate structure 400G.

The buried gate structure 400G may include a gate dielectric layer 106 that covers the bottom surface and the sidewalls of the trench 105, and a gate electrode 410 and a gate capping layer 120 that are sequentially stacked to fill the trench 105 over the gate dielectric layer 106.

The gate electrode 410 may include a lower gate 411, an upper gate 413, and a vertical gate 414. The lower gate 411, the upper gate 413, and the vertical gate 414 may correspond to the lower gate 311, the upper gate 313, and the vertical gate 314 shown in FIG. 6B, respectively.

The lower gate 411 may include a barrier layer 415 and a low resistance gate electrode 416. The barrier layer 415 may be conformally formed on the surface of the gate dielectric layer 106. The barrier layer 415 may include a metal-containing material. The barrier layer 415 may include a metal nitride. The barrier layer 415 may include, for example, titanium-nitride or tantalum nitride.

Referring to FIG. 6E, the semiconductor device may include a buried gate structure 401G, a first doped region 107, and a second doped region 108. An isolation layer 102 and an active region 103 may be formed in the substrate 101. Also, a trench 105 crossing the active region 103 and the isolation layer 102 may be formed. A buried gate structure 401G may be formed in the trench 105. A channel may be formed between the first doped region 107 and the second doped region 108 by the buried gate structure 401G. The channel may be defined according to the profile of the trench 105.

The buried gate structure 401G may be disposed in the trench 105. The buried gate structure 401G may be disposed in the active region 103 between the first doped region 107 and the second doped region 108 and extend into the isolation layer 102. A fin region 103F may be positioned in the active region 103 below the buried gate structure 401G.

The buried gate structure 401G may include a gate dielectric layer 106 that covers the bottom surface and the sidewalls of the trench 105, and a gate electrode 410 and a gate capping layer 120 that are sequentially stacked to fill the trench 105 over the gate dielectric layer 106. The buried gate structure 401G may further include a spacer 130 between the gate capping layer 120 and the gate dielectric layer 106.

The gate electrode 410 may include a lower gate 411, an upper gate 413, and a vertical gate 414. The lower gate 411, the upper gate 413, and the vertical gate 414 may correspond to the lower gate 311, the upper gate 313, and the vertical gate 314 shown in FIG. 6B, respectively.

Referring to FIG. 6F, the semiconductor device may include a buried gate structure 500G, a first doped region 107, and a second doped region 108. An isolation layer 102 and an active region 103 may be formed in the substrate 101. Also, a trench 105 crossing the active region 103 and the isolation layer 102 may be formed. A buried gate structure 500G may be formed in the trench 105. A channel may be formed between the first doped region 107 and the second doped region 108 by the buried gate structure 500G. The channel may be defined according to the profile of the trench 105.

The buried gate structure 500G may be disposed in the trench 105. The buried gate structure 500G may be disposed in the active region 103 between the first doped region 107 and the second doped region 108 and extend into the isolation layer 102. A fin region 103F may be positioned in the active region 103 below the buried gate structure 500G.

The buried gate structure 500G may include a gate dielectric layer 106 that covers the bottom surface and the sidewalls of the trench 105, and a gate electrode 510 and a gate capping layer 120 that are sequentially stacked to fill the trench 105 over the gate dielectric layer 106.

The gate electrode 510 may include a lower gate 511, an upper gate 513, and a vertical gate 514. The lower gate 511 may include a first barrier layer 515 and a low resistance gate electrode 516. A second barrier layer 517 may be formed between the vertical gate 513 and the first barrier layer 515. The first barrier layer 515 and the low-resistance gate electrode 516 may correspond to the barrier layer 415 and the low-resistance gate electrode 416 shown in FIG. 6D, respectively. For example, the low-resistance gate electrode 516 may be formed of tungsten (W), and the first barrier layer 515 may be formed of titanium nitride (TiN). Therefore, the lower gate 511 may include a ‘TiN/W stack’. The upper gate 513 may include, for example, tungsten and the vertical gate 514 may include N-type polysilicon.

The second barrier layer 517 may be formed over the first barrier layer 515. The second barrier layer 517 may be formed between the first barrier layer 515 and the vertical gate 514. Also, the second barrier layer 517 may be formed between the gate dielectric layer 106 and the upper gate 513. The first barrier layer 515 and the second barrier layer 517 may be the same material or different materials. The second barrier layer 517 may include a metal nitride.

The second barrier layer 517 may have the same thickness as the thickness of the vertical gate 514. The thickness of the second barrier layer 517 may be changed diversely according to the thickness of the vertical gate 514. The vertical gate 514, the first barrier layer 515, and the second barrier layer 517 may have the same thickness.

The second barrier layer 517 may be formed by a plasma nitridation process. For example, the second barrier layer 517 may be formed by exposing the upper surfaces of the low-resistance gate electrode 516 and the first barrier layer 515 to the plasma nitridation process.

Referring to FIG. 6G, the semiconductor device may include a buried gate structure 501G, a first doped region 107, and a second doped region 108. An isolation layer 102 and an active region 103 may be formed in the substrate 101. Also, a trench 105 crossing the active region 103 and the isolation layer 102 may be formed. The buried gate structure 501G may be formed in the trench 105. A channel may be formed between the first doped region 107 and the second doped region 108 by the buried gate structure 501G. The channel may be defined according to the profile of the trench 105.

The buried gate structure 501G may be disposed in the trench 105. The buried gate structure 501G may be disposed in the active region 103 between the first doped region 107 and the second doped region 108 and extend into the isolation layer 102. A fin region 103F may be positioned in the active region 103 below the buried gate structure 501G.

The buried gate structure 501G may include a gate dielectric layer 106 that covers the bottom surface and the sidewalls of the trench 105, and a gate electrode 510 and a gate capping layer 120 that are sequentially stacked to fill the trench 105 over the gate dielectric layer 106.

The gate electrode 510 may include a lower gate 511, an upper gate 513, and a vertical gate 514. The lower gate 511 may include a first barrier layer 515 and a low resistance gate electrode 516. A second barrier layer 517 may be formed between the vertical gate 514 and the first barrier layer 515. The buried gate structure 501G may further include a spacer 130 extending vertically over the vertical gate 514.

According to the embodiments of the present invention, the reliability of the semiconductor device may be improved by improving the film quality of a gate dielectric layer.

According to the embodiments of the present invention, the reliability of the semiconductor device may be improved by minimizing the damage of a hard mask layer.

While the present invention has been described with respect to specific embodiments, it will be apparent to those skilled in the art that various changes and modifications may be made without departing from the spirit and scope of the invention as defined in the following claims.

What is claimed is:

1. A method for fabricating a semiconductor device, the method comprising:
forming a hard mask layer over a semiconductor substrate;
forming a trench by etching the semiconductor substrate with the hard mask layer;
forming a gate dielectric layer on a surface of the trench while hardening the hard mask layer; and
forming a gate electrode partially filling the trench over the gate dielectric layer.

2. The method of claim 1, wherein the hard mask layer is formed at a lower temperature than a temperature that the gate dielectric layer is formed.

3. The method of claim 1, wherein the hard mask layer includes a low temperature oxide.

4. The method of claim 1, wherein the hard mask layer includes an Ultra Low Temperature Oxide (ULTO).

5. The method of claim 1, wherein the gate dielectric layer includes silicon oxide.

6. The method of claim 1, wherein the forming of the gate dielectric layer is performed at a temperature of approximately 500° C. to 900° C.

7. The method of claim 1, wherein the forming of the gate dielectric layer is performed by an atomic layer deposition method in a furnace.

8. The method of claim 1, wherein the forming of the gate electrode includes:
forming a gate layer filling the trench over the gate dielectric layer; and
recessing the gate layer to form the gate electrode having a lower level than that of an upper surface of the semiconductor substrate in the trench.

9. The method of claim 1, further comprising:
performing an oxidation process of the gate dielectric layer and the hard mask layer, after the forming of the gate dielectric layer.

10. The method of claim 9, wherein the oxidation process is performed at the same temperature as the temperature of the forming of the gate dielectric layer or at a higher temperature than the temperature of the forming of the gate dielectric layer.

11. The method of claim 1, further comprising after the forming of the gate electrode:
forming a gate capping layer over the gate electrode;
forming a first source/drain region and a second source/drain region in the semiconductor substrate;
forming a bit line structure contacting the first source/drain region; and
forming a contact plug contacting the second source/drain region.

12. The method of claim 11, wherein the forming of the contact plug includes:
forming a contact hole exposing the second source/drain region by etching the hard mask layer;
widening a bottom portion of the contact hole by a wet etching process; and
forming a storage node contact plug in the widened contact hole.

13. A method for fabricating a semiconductor device, comprising:
forming a hard mask layer in a semiconductor substrate;
forming a trench by etching the semiconductor substrate with the hard mask layer;
forming a gate dielectric layer having a wet etch rate that is different from a wet etch rate of the hard mask layer on a surface of the trench;
forming a buried gate structure filling the trench over the gate dielectric layer;
forming a first source/drain region and a second source/drain region in the semiconductor substrate on both sides of the buried gate structure;
forming a bit line structure contacting the first source/drain region; and
forming a storage node contact plug contacting the second source/drain region.

14. The method of claim 13, wherein the hard mask layer is formed at a lower temperature than a temperature that the gate dielectric layer is formed.

15. The method of claim 13, wherein the hard mask layer includes silicon oxide, such as an Ultra Low Temperature Oxide (ULTO).

16. The method of claim 13, wherein the hard mask layer includes silicon oxide having a wet etch rate that is higher than a wet etch rate of the gate dielectric layer.

17. The method of claim 13, wherein the gate dielectric layer is formed by an atomic layer deposition method at a temperature of approximately 500° C. to 900° C.

18. The method of claim 13, further comprising:
performing an oxidation process of the gate dielectric layer and the hard mask layer, after the forming of the gate dielectric layer.

19. The method of claim 18, wherein the oxidation process is performed at the same temperature as a temperature of the forming of the gate dielectric layer or at a higher temperature than the temperature of the forming of the gate dielectric layer.

20. The method of claim 13, wherein the forming of the storage node contact plug includes:
forming a contact hole exposing a second source/drain region by etching the hard mask layer;
widening a bottom portion of the contact hole by a wet etching process; and
forming the storage node contact plug in the widened contact hole.
